(19) United States
(12) Patent Application Publication
(10) Pub. No.: US 2006/0256615 A1
(43) Pub. Date: Nov. 16, 2006

(54) Horizontal and vertical error correction coding (ECC) system and method

(76) Inventor: Thane M. Larson, Roseville, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/125,767

(22) Filed: May 10, 2005

(51) Int. Cl. G11C 16/06

(52) U.S. Cl. 365/185.09

(57) ABSTRACT

A method and system detects and corrects errors in data bits of data words stored in a system memory. Each data word includes a plurality of data bits and the method includes generating a horizontal error correcting code for each data word. Vertical error correcting codes are generated, with each vertical error correcting code being generated using a particular bit from all of the data words. Each vertical and horizontal error correcting code is stored in the system memory. Vertical scrubbing is performed using the vertical error correcting codes to detect and possibly correct errors in the data words and horizontal scrubbing is performed using the horizontal error correcting codes to detect and correct errors in the data words. The vertical scrubbing may be done automatically either through suitable hardware contained on memory modules in the system memory or by a memory controller.

### BACKGROUND OF THE INVENTION

Modern computer systems include ever increasing amounts of system memory in which the computer system stores programs and data that are currently in use. Even a typical personal computer system may now include several gigabytes of dynamic random access memory (DRAM), which typically forms the largest portion of system memory. Server computer systems, such as a Web server, may include hundreds of gigabytes or even terabytes of DRAM to store programs and data associated with a Web site or a corporate database.

The larger the storage capacity of a system memory the more likely that errors in data and programs stored in the memory will occur. Note that in the present discussion the term “data” will be used to refer to any type of data stored in the system memory, including program instructions and data generated and utilized by programs currently being executed by the computer system. For a system memory including a gigabyte of DRAM, there are eight billion (8,000,000,000) individual DRAM memory cells or locations (assuming 8 bits of data per byte), each location typically storing a single bit of data. With such a large number of memory locations, errors in data bits can occur for a variety of different reasons, such as electrical noise, thermal noise, and high-energy particles like neutrons and alpha particles impacting the memory locations. For example, a high-energy particle impacting a DRAM memory location may change the amount of charge stored by that location and thereby cause the stored data bit corresponding to the stored charge to change from a logic 1 to a logic 0, or vice versa.

Errors in the data stored in system memory can result in a program providing a user with erroneous results or can cause the computer system to crash. As a result, various approaches have been utilized in system memories to prevent data errors from adversely affecting the operation of the computer system. One such approach is known as “memory mirroring” in which a duplicate copy of data is stored in the system memory. With this approach, upon the detection of data error in a primary copy of the data, the duplicate copy of the data is utilized. This approach is costly both in terms of dollars and in terms of physical space due to the requirement of doubling the size of the actual required memory capacity.

To actually detect and correct erroneous data bits, a variety of approaches are utilized in conventional system memories. The most common is the detection of erroneous data bits through the addition of a parity bit. A parity bit is a bit added to a byte of data to make the number of logic 1 s in the byte and parity bit either even or odd, as will be understood by those skilled in the art. A more advanced approach to both detect and correct erroneous data bits is through the use of error correcting codes (ECCs). The most commonly utilized ECC is a code capable of detecting single and double bit data errors and capable of correcting single bit data errors. This type of ECC code is known as a single error correction double error detection (SECDED) code.

FIG. 1 is a memory diagram of a conventional system memory illustrating the storage of data in the form of data words DW1-DWN along with horizontal error correcting codes HECC1-HECCN for each of these words. The memory diagram illustrates that a typical system memory may be viewed as storing data in an array of individual memory cells or locations ML, several of which are shown in the upper left corner of the memory diagram. The array is an N×(M+K) array of memory locations ML, and thus includes N rows of memory locations and M+K columns of memory locations. Each word DW1-DWN is M bits wide and each horizontal error correcting code HECC1-HECCN is K bits wide. When referring to the words DW1-DWN and codes HECC1-HECCN in the following description, the data words and codes will be referred to simply as DW and HECC, respectively, when referring to any or all of the words or codes, while the specific row designation 1-N will be included only when referring to a specific one of the words or codes. The same may be true of other reference numbers and letters utilized below with reference to other figures of the present application.

In operation, the system memory utilizes the horizontal error correcting codes HECC to detect and correct erroneous data bits in the associated words DW The specific way in which the codes HECC are calculated from the data bits in the corresponding data word DW along with the way the codes are utilized to detect and correct erroneous data bits in the associated words will be understood by those skilled in the art, and thus, for the sake of brevity, will only be described generally herein. Briefly, before each data word DW is stored in the system memory an algorithm is applied to the data bits in the data word DW to thereby generate the corresponding HECC code. The data word DW along with the HECC code are then stored in the system memory. As will be appreciated by those skilled in the art, data in the form of the data words DW and the HECC codes may only be written to and read from the system memory one row at a time.

To detect erroneous data bits in each data word DW, the data word along with the corresponding HECC code are read from the system memory and the same algorithm is once again applied to the data bits in the read data word to generate a newly calculated HECC code. If the newly calculated HECC code does not equal the HECC code read from the system memory, then an error in the data bits of the data word DW has occurred. The algorithm generates the HECC codes in such a way that the values of the codes allow a certain number of erroneous data bits in the data word DW to be corrected. The rows of memory locations ML are sequentially read one row at a time and this process repeated for each read data word DW to detect and correct erroneous data bits in that data word.

The system memory performs this detection and correction on each of the words DW whenever that word is accessed during normal operation of the computer system containing the system memory. In addition, the system memory typically executes a process that will be referred to herein as “horizontal scrubbing.” Horizontal scrubbing is a background process periodically executed by the system memory in which each data word DW and the associated code HECC are accessed and any errors detected and corrected. Such horizontal scrubbing is done independent of whether the data word DW is accessed during normal operation of the computer system and is ideally done frequently enough to ensure that single bit errors in any of the words do not become double bit errors.

Typically, the HECC codes are Hamming SECDED codes, meaning that each code can detect and correct a single bit error in the associated word DW and can detect double bit errors in that word. Hamming is the particular type of code and defines the way in which these SECDED codes are generated, as will be understood by those skilled in the art. As can be seen from the memory diagram, the overall storage capacity of the illustrated system memory is N×(M+K) bits of data. Note that the HECC codes occupy N×K of this overall storage capacity. If more sophisticated error detection and correction is desired, such as the ability to correct double bit errors, the width K of the HECC codes becomes even greater. This greater width K means that these codes undesirably occupy a greater percentage of the overall storage capacity of the system memory. As a result, the overall storage capacity of the system memory must be increased, which undesirably increases the size and cost of the system memory.

FIG. 2 is a memory diagram of a system memory illustrating another error detection and correction approach that reduces the percentage of the overall storage capacity of the system memory that is required for error correction and detection. With this approach, the system memory is formed by a (N+1)×(M+1) array of memory locations, where N is the number of rows storing a data word DW1-DWN and M is the width of each data word. A single horizontal parity bit HP1-HPN is stored for each data word DW1-DWN. Similarly, for each column of memory locations in the array a corresponding single vertical parity bit VP1-VPM is stored. As a result, only N+M memory locations in the system memory are required to store the parity bits HP and VP, which is a much smaller percentage of the overall storage capacity when compared to the approach of FIG. 1. Note that for ease of description rows of memory locations are designated as being in a horizontal direction while columns of memory locations are designated as being in a vertical direction.

In operation, the system memory utilizes the horizontal parity bits HP and vertical parity bits VP to detect and correct single bit errors. For example, if any of the horizontal parity bits HP indicates an erroneous bit in the corresponding data word DW, the system memory then checks the vertical parity bits VP. One of the vertical parity bits VP will indicate an error in the corresponding bits of the data words DW in that column. The vertical parity bit VP that indicates the error signals the specific location of the erroneous bit in the data word DW that was determined to have such an erroneous bit by the corresponding horizontal parity bit HP. For example, FIG. 2 illustrates an erroneous data bit E contained in the data word DW4. In this situation, the horizontal parity bit HP4 will indicate an error in one of the bits in the data word DW4 and the vertical parity bit VP3 would similarly indicate an error in one of the bits in that column. From the parity bits HP4 and VP3, the system memory determines the third bit from the left in the data word DW4 is erroneous and then corrects this bit.

While the approach illustrated in FIG. 2 is efficient in terms of requiring fewer memory locations to store the parity bits HP and VP utilized error detection and correction, this approach is very slow and thus has not been widely utilized commercially, if at all. The approach is slow because each memory location in the array must be accessed twice. Also note that this approach is limited to detecting and correcting single bit errors.

Another error checking and correction approach involves distributing bits of data among the memory locations in such a way that the failure of one component in the system memory may still be detected and corrected. This approach may be generically referred to as “enhanced ECC” and is referred to using different names by different companies in the memory industry. For example, International Business Machines Corp. uses the trademark “Chipkill” and Hewlett-Packard Co. uses the trademark “Chip Spare” to refer to this ECC approach. DRAM system memory is commonly formed by a number of dual in-line memory modules (DIMMs), and with the enhanced ECC approach bits of data are distributed among the DIMMs. In this way, the computer system may access data words that include bits from a number of the DIMMs such that the failure of any one of the DIMMs can be detected and the bits in the data word from the failed DIMM corrected.

There is a need for an improved system and method of detecting and correcting multiple bit errors in system memories without excessively increasing the portion of such memory for storing error correcting codes required for such detection and correction.

### SUMMARY OF THE INVENTION

According to one aspect of the present invention, a method and system detects and corrects errors in data bits of data words stored in a system memory. Each data word includes a plurality of data bits and the method includes generating a horizontal error correcting code for each data word and storing each horizontal error correcting code in the system memory. Vertical error correcting codes are generated, with each vertical error correcting code being generated using a particular bit from all of the data words. Each vertical error correcting code is stored in the system memory. Vertical scrubbing is performed using the vertical error correcting codes to detect errors in the data words and horizontal scrubbing is performed using the horizontal error correcting codes to detect and correct errors in the data words.

The vertical scrubbing may also correct detected errors. The horizontal and vertical error correcting codes may, for example, be SECDED codes, enabling detection and correction during both horizontal and vertical scrubbing. Alternatively, the horizontal error correcting code may be a SECDED code and the vertical error correcting code a parity bit, meaning vertical scrubbing detects errors and horizontal scrubbing corrects such detected errors. The vertical scrubbing may be done automatically either through suitable hardware contained on memory modules in the system memory or by a memory controller in the system memory.

### BRIEF DESCRIPTION OF THE DRAWINGS

FIG. 1 is a memory diagram of a conventional system memory illustrating the storage of data words DW1-DWN along with associated horizontal error correcting codes.

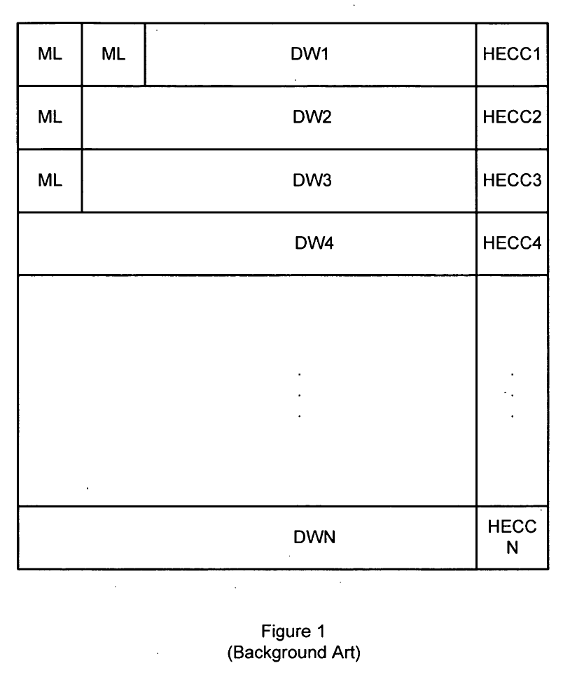

FIG. 2 is a memory diagram of a system memory illustrating another error detection and correction approach that reduces the percentage of the overall storage capacity of the system memory that is required for error correction and detection.

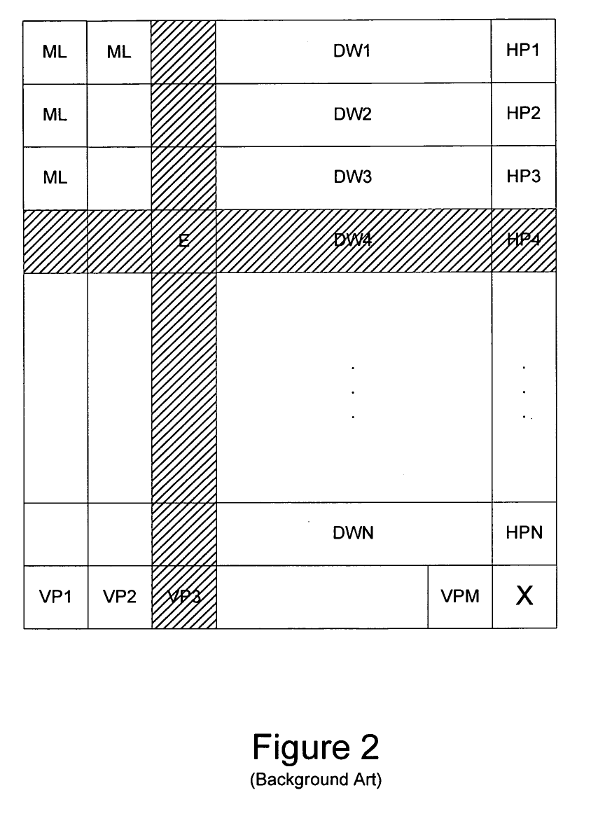

FIG. 3 is a memory diagram illustrating horizontal and vertical error correcting codes that may be used in detecting and correcting multiple bit errors in associated data words according to one embodiment of the present invention.

FIG. 4 illustrates an error correction process utilizing the horizontal and vertical error correcting codes to detect and correct multiple bit errors in the data words of FIG. 3 according to one embodiment of the present invention.

FIG. 5 is a flowchart illustrating an error correction process according to another embodiment of the present invention.

FIG. 6 is a functional block diagram of a computer system 600 including a system memory 602 formed by a memory subsystem 604 and a memory controller 606 that is part of a chipset 608.

### DETAILED DESCRIPTION OF PREFERRED EMBODIMENTS

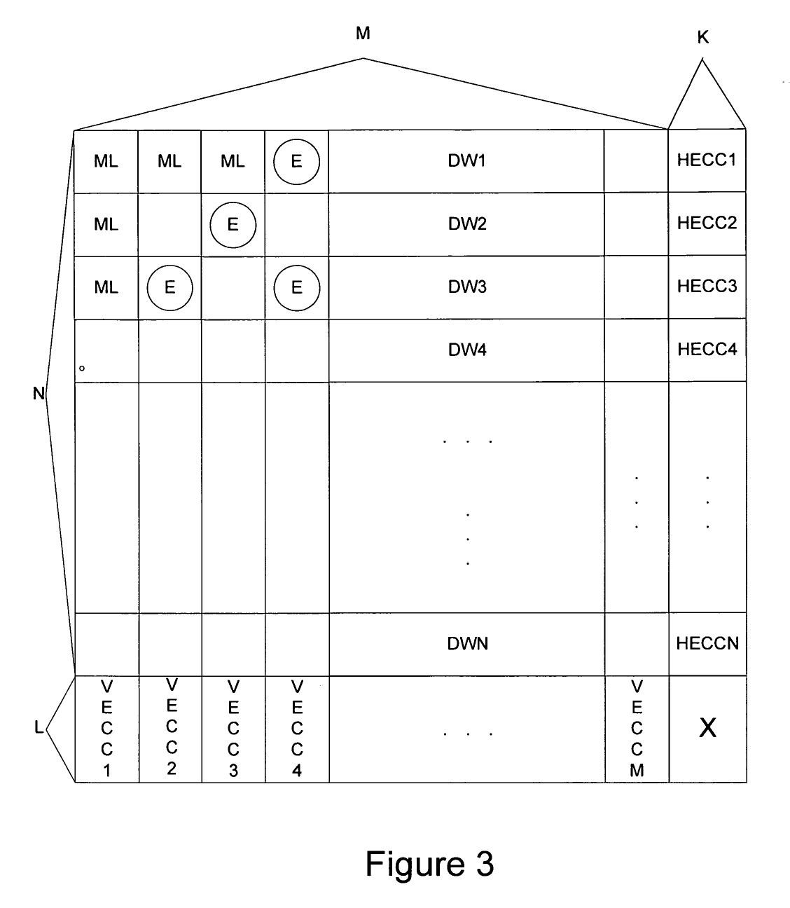

FIG. 3 is a memory diagram illustrating horizontal error correcting codes HECC1-HECCN and vertical error correcting codes VECC1-VECCM that may be used in detecting and correcting multiple bit errors in associated data words DW1-DWN in a system memory according to one embodiment of the present invention. By utilizing the horizontal and vertical error correcting codes HECC and VECC in combination, multiple bit errors may be detected and corrected using conventional codes that are individually capable of correcting only a smaller number of bits, such as Hamming SECDED codes for the HECC and VECC codes. Moreover, by implementing vertical scrubbing hardware circuitry that utilizes the VECC codes to detect and correct errors and software that utilizes the HECC codes, the speed at which such errors are detected and corrected may be increased, as will be explained in more detail below. In one embodiment, the vertical scrubbing hardware circuitry that utilizes the VECC codes automatically executes a “vertical scrub” of the system memory to detect and correct single bit errors, and the HECC codes are thereafter utilized in correcting any multiple bit errors that were erroneously corrected through this vertical scrubbing process, as will also be explained in more detail below.

In the following description, certain details are set forth in conjunction with the described embodiments of the present invention to provide a sufficient understanding of the invention. One skilled in the art will appreciate, however, that the invention may be practiced without these particular details. Furthermore, one skilled in the art will appreciate that the example embodiments described below do not limit the scope of the present invention, and will also understand that various modifications, equivalents, and combinations of the disclosed embodiments and components of such embodiments are within the scope of the present invention. Embodiments including fewer than all the components of any of the respective described embodiments may also be within the scope of the present invention although not expressly described in detail below. Finally, the operation of well known components and/or processes has not been shown or described in detail below to avoid unnecessarily obscuring the present invention.

FIG. 3 illustrates an array of memory cells or locations ML, with several memory locations once again be illustrated in the upper left-hand corner of the array. The array includes N+L rows of memory locations ML and M+K columns of memory locations, and is thus a (N+L)×(M+K) array. Stored in respective rows of the array are data words DW1-DWN, each data word being M bits wide and having an associated horizontal error correcting code HECC1-HECCN that is K bits wide stored in memory locations ML in the same row. The additional L rows times M columns of the array store the vertical error correcting codes VECC1-VECCM in respective columns of memory locations ML. Each VECC code is associated with a particular column of data bits in the data words DW For example, the vertical error correcting code VECC2 is calculated from the data bits in the second column of each data word DW1-DWN, which may be designated DW1<2>-DWN<N>.

In one embodiment of the present invention, both the horizontal error correcting codes HECC and vertical error correcting codes VECC are Hamming SECDED codes. Thus, each HECC code can correct a single bit error in the corresponding data word DW and detect a double bit error in that data word. Similarly, each VECC code can correct a single bit error in the corresponding column of data bits of the data words DW and can detect a double bit error in this column of data bits. Note that other types of error correcting codes may be utilized for the horizontal and vertical error correcting codes HECC and VECC in other embodiments of the present invention, including codes capable of detecting and correcting more erroneous data bits. Also, in one embodiment of the present invention each of the vertical error correcting codes VECC is a single parity bit, as will be discussed in more detail below.

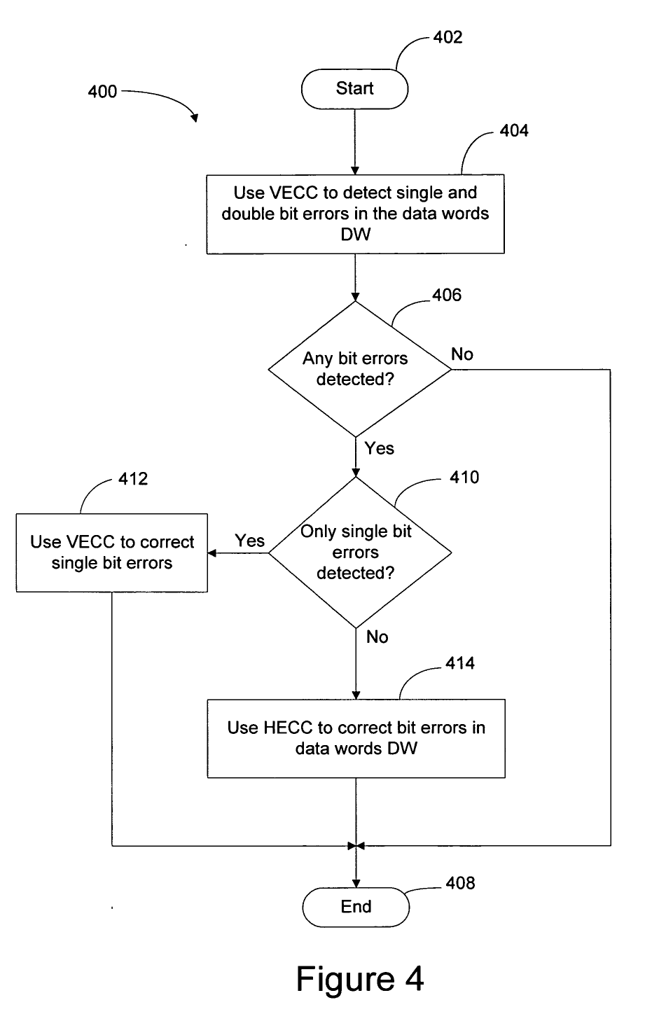

A process utilizing the horizontal error correcting codes HECC and vertical error correcting codes VECC of FIG. 3 in detecting and correcting erroneous data bits in the data words DW will now be described in more detail with reference to the flowchart of FIG. 4. FIG. 4 illustrates an error correction process 400 utilizing the horizontal and vertical error correcting codes HECC and VECC to detect and correct multiple bit errors in the data words DW according to one embodiment of the present invention. This is true even though each of the HECC and VECC codes is a Hamming SECDED code in the sample embodiment being described.

Assume initially that all of the data words DW1-DWN have been written into and stored in respective rows of the system memory, and that as part of this process the horizontal error correcting codes HECC1-HECCN for each data word were calculated and stored along with the data word. Also, as each of the data words DW was being written into the corresponding row in the system memory, the bits in that data word are also utilized in calculating the vertical error correcting codes VECC1-VECCM. Each calculated vertical error correcting code VECC1-VECCM is stored in columns of memory locations ML in the system memory as illustrated in FIG. 3.

The process 400 begins in step 402 and proceeds immediately to step 404 in which the vertical error correcting codes VECC are utilized to detect single and double bit errors in the corresponding columns of data bits of the data words DW The step 404 includes accessing each of the N data words DW stored in the system memory. When each data word DW is accessed, the respective bits in that data word are stored or otherwise applied to circuitry (not shown) in the system memory such that after all N data words have been accessed a new value for each of the vertical error correcting codes VECC1-VECCM may be calculated. The previously calculated values for the vertical error correcting codes VECC1-VECCM are also accessed, and each compared to the newly calculated value for that code (e.g., the newly calculated value for VECC1 is compared to the previous value for VECC1 stored in the memory). From this comparison, the process determines whether single or double errors exist in any of the columns of data bits associated with the VECC codes. This process of utilizing the VECC codes to detect single and double bit errors in the corresponding columns of data bits of the data words DW may be referred to as “vertical scrubbing” in the following description.

At this point, the process proceeds to step 406 and determines whether any single or double bit errors have been detected in step 404. When this determination is negative, the process goes immediately to step 408 and ends. No further action is needed because no erroneous data bits in the data words DW were detected using the VECC codes.

When the determination in step 406 is positive, meaning at least one single and double bit error was detected for the columns of data bits associated at least one of the VECC codes, the process goes to step 410. In step 410, the process determines whether only single bit errors were detected in the data words DW via the VECC codes. If this is true, the process goes to step 412 and corrects all detected single bit errors using the appropriate VECC codes. For example, referring to FIG. 3 a single erroneous data bit exists in the third column of data bits associated with the vertical error correcting code VECC3, as indicated by the letter “E” enclosed in a circle for this memory location. Assuming this is the only detected single bit error, then in step 412 the process utilizes the newly calculated and previously stored values for the VECC3 code to correct this erroneous data bit.

After all single bit errors have been corrected in step 412, the process proceeds to step 408 and terminates. There is no need to utilize the HECC codes in this situation because the VECC codes, which are SECDED Hamming codes in this example, have been used to detect and correct all single bit errors in the associated columns of data bits in the data words DW Note that multiple VECC codes could indicate errors and thus multiple bits within a given data word DW could actually be corrected via the vertical error correcting codes. For example, the data word DW3 could include erroneous data bits DW3<2> and DW3<4> as shown in FIG. 3 by the letter “E” in circles. In this situation, the data word DW3 includes two erroneous bits, but each of these errors is only a single bit error in the vertical dimension and may be corrected using the vertical error correcting codes VECC2 and VECC4.

Returning to step 410, when the determination in this step is negative this means that at least one double bit error was detected in step 404 using the VECC codes. For example, a double bit error is shown in FIG. 3 for the column of data bits associated with the vertical error correcting code VECC4. These errors correspond to the bits DW1<4> and DW3<4> in the column of data bits associated with the VECC4 code. When step 410 determines at least one double bit error exists, the process goes to step 414 and utilizes the horizontal error correcting codes HECC to “scrub” the data words and correct all bit errors. This process is analogous to that previously described for the VECC codes. More specifically, each data word DW is accessed along with the associated horizontal error correcting code HECC. The bits of the accessed data word DW are then used to calculate new value for the associated horizontal error correcting code HECC.

The previously calculated value for the horizontal error correcting code HECC that was read from the memory is then compared to the newly calculated value for that code (e.g., the newly calculated value for HECC2 is compared to the previous value for HECC2 read from memory). From this comparison, the process determines detects and corrects all single bit error in each of the data words DW. Note that this description assumes no double bit errors exist in any of the data words DW, which could occur as illustrated in FIG. 3 for the data bits DW3<2> and DW3<4> in the data word DW3. After scrubbing all data words DW1-DWN in step 414, the process goes to step 408 and terminates.

The likelihood of a double bit error in one of the data words DW would typically be relatively low so this situation does not present a serious limitation to utility of the error correction process 400. To further reduce the likelihood of such an occurrence, the error correction process 400 may be modified such that all single bit errors detected using the VECC codes are corrected using these codes prior to performing horizontal scrubbing using the HECC codes. In this embodiment, the process corrects all single bit errors detected using the VECC codes. Only after this is done and at least one of the VECC codes has detected a double bit error does the process perform horizontal scrubbing using the HECC codes. Returning to FIG. 3, this embodiment would eliminate the double bit errors DW3<2> and DW3<4> in the data word DW3. This is true because the single bit error in DW3<2> would be corrected by the associated vertical error correcting code VECC2 so that only the single bit error DW3<4> would exist in the data word DW3 when doing the horizontal scrubbing. During horizontal scrubbing, the HECC3 code is used to correct this single bit error in DW3<4>. In the event that a double bit error is detected in any of the data words DW during horizontal scrubbing, such errors would typically be reported to the operating system of the computer system of which the system memory is a part.

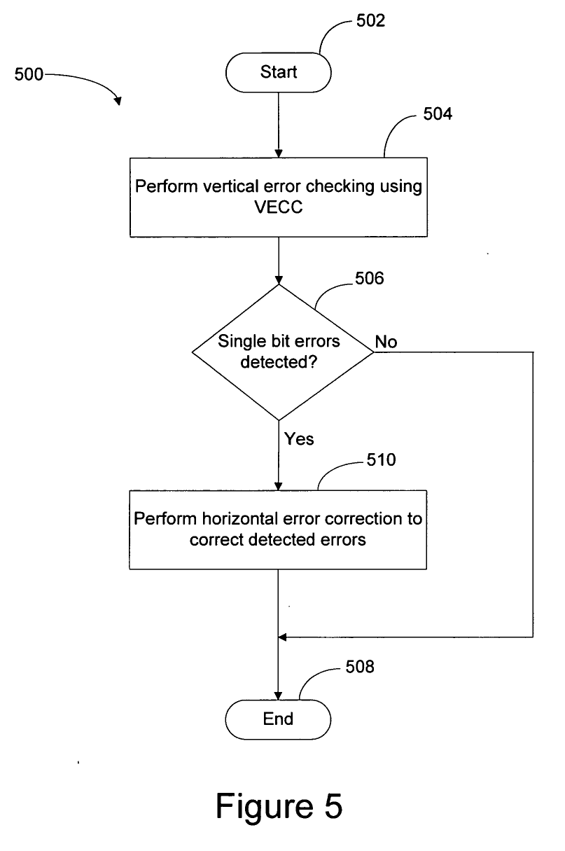

Other embodiments of the error correcting processes utilizing the code HECC and VECC are possible, and such processes may vary depending on the application of the system memory in which the process is being utilized. Also, the type of codes utilized for the HECC and VECC codes may similarly vary depending on the application as previously mentioned, and the type of each code may also affect the specific process that is executed. For example, FIG. 5 is a flowchart illustrating an error correction process 500 according to another embodiment of the present invention. In the process of FIG. 5, the horizontal error correcting codes HECC are again assumed to be Hamming SECDED codes while each of the vertical error correcting codes VECC is a single parity bit.

The error correction process 500 begins in step 502 and proceeds immediately to step 504 in which the process utilizes the vertical error correcting codes VECC to detect single bit errors in the associated columns of bits in the data words DW Because each of the VECC codes is a single parity bit in this embodiment, only single bit errors can be detected and no errors corrected using the VECC codes. In detecting single bit errors using the single parity bit VECC codes, each of the N data words DW stored in the system memory is accessed and respective bits in that data word stored or otherwise applied to circuitry (not shown) in the system memory such that after all N data words have been accessed a new value for each of the parity bit VECC1-VECCM codes may be calculated. The previously calculated values for the parity bits VECC1-VECCM are also accessed, and each previously calculated parity bit compared to the newly calculated parity bit (e.g., the newly calculated parity bit VECC1 is compared to the previously calculated parity bit VECC1 stored in the memory). From this comparison, the process determines whether any single bit errors exist in any of the columns of data bits associated with the VECC codes.

After all parity bits VECC having utilized to determine whether any single bit errors exist in the corresponding column of data bits in step 504, the process proceeds to step 506 and determines whether any single bit errors have been detected. If the determination in step 506 is negative, the process proceeds to step 508 and terminates since there are no detected single bit errors and thus presumably no errors in the data bits of any of the data words DW1-DWN. When the determination in step 506 is positive, at least one single bit error exists in at least one of the data words DW and the process proceeds to step 510. In step 510 the process performs horizontal scrubbing of the data words DW using the horizontal error correcting codes HECC as previously described. Single bit errors in the data words DW are detected and corrected using the HECC codes during this horizontal scrubbing. Note that it is possible that one or more of the data words DW could include multiple bit errors that cannot be corrected in this embodiment. Since the HECC codes are Hamming SECDED codes in this example embodiment, during horizontal scrubbing any double bit errors in any of the data words DW may be detected but not corrected. Any such detected double bit errors once again would typically be reported to the operating system of the computer system of which the system memory is a part.

In another error correction process according to another embodiment, the orders in which the VECC and ECC codes are utilized to detect and correct error as shown and described with reference to FIG. 4 is reversed. Thus, the HECC codes are first used to detect and correct errors in the data words DW and then, upon the detection of a double bit error, the VECC codes are utilized to correct such an error.

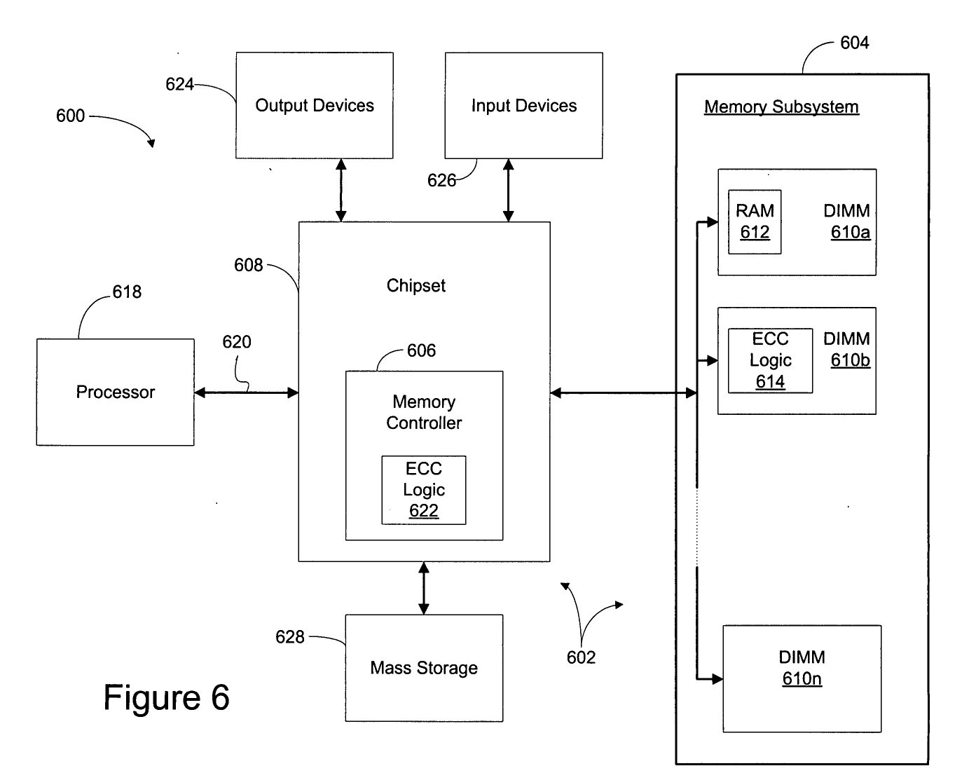

FIG. 6 is a functional block diagram of a computer system 600 including a system memory 602 formed by a memory subsystem 604 and a memory controller 606 that is part of a chipset 608. The memory subsystem 604 includes a number of dual in-line memory modules (DIMMs) 610a-n, each DIMM including a number of DRAM memory devices 612, one of which is shown on the DIMM 610a. Each DIMM 610 further includes error checking and correction (ECC) logic 614 as shown only for the DIMM 610b. The ECC logic 614 on each DIMM 610 is hardware logic circuitry that performs the vertical scrubbing of data words stored in the corresponding DRAM memory devices 612 using VECC codes as previously described with reference to FIG. 4 or parity bits for the VECC codes as described with reference to FIG. 5.

Each of the DIMMs 610 includes address, data, and control buses that are collectively illustrated as a memory bus 616 in FIG. 6, with each of the DRAM memory devices 612 on each DIMM being coupled, in turn, to memory bus 616. The details of this coupling of the DIMMs 610 and memory devices 612 to the memory bus 616 vary depending on a variety of different factors, such as the width of the data bus of each memory device, the number of ranks of memory devices on each DIMM, and so on, as will be appreciated by those skilled in the art. Such details are not integral to an understanding of the embodiment of the present invention illustrated in FIG. 6, and thus, for the sake of brevity, will not be discussed more herein.

The chipset 608 includes the memory controller 606, which is coupled to the DIMMs 610 through the memory bus 616. The memory controller 606 applies commands in the form of address, data, and control signals to the DIMMs 610 over the memory bus 616 to read data from and write data to the DIMMs. The memory controller 606 supplies these commands to the DIMMs 610 in response to requests from a processor 618 applied to the controller over a system bus 620. The memory controller 606 includes ECC logic 622 that performs the horizontal scrubbing of data words stored in the DIMMs 610 using HECC codes stored in these DIMMs as previously described with reference to FIGS. 4 and 5. In addition, the ECC logic 622 performs error detection and correction using the HECC codes on data words being read from the memory subsystem 604. The controller 606 also generates the HECC codes for data words being written to the memory subsystem 604 and stores these codes in the DIMMs 610 along with the data words.

The computer system 600 further includes one or more output devices 624 coupled to the processor 618 through the chipset 608. Typical output devices 624 include a printer and a video terminal. One or more input devices 626 are also coupled to the processor 618 through the chipset 608, such as a keyboard and a mouse. Mass storage devices 628 are also typically coupled to the processor 618 through the chipset 608 to store and retrieve large amounts of data from external storage media (not shown). Examples of typical Mass storage devices 628 include hard and floppy disks, tape cassettes, compact disk read-only (CD-ROMs) and compact disk read-write (CD-RW) memories, and digital video disks (DVDs). The chipset 608 also performs all communications and control between the processor and the devices 624-628 and performs a variety of other functions, such as supplying video data to a video driver (not shown) that drives a video monitor corresponding to one of the output devices 624 and transferring data from the mass storage devices 628 to the memory subsystem 604, as will be appreciated by those skilled in the art.

In operation of the computer system 600, the processor 618 executes programs (not shown) to perform desired functions. When the processor 618 requires programming instructions or data stored in the memory subsystem 604 the processor applies an appropriate command to the memory controller 606 over the system bus 620. In response to the command, the memory controller 606 applies a corresponding command to the DIMMs 610 over the memory bus 616 to access the requested data. In response to this command from the memory controller 606, the DIMMs 610 access the corresponding data words and return the requested data words along with the corresponding HECC codes to the memory controller over the memory bus 616. The memory controller 606 then utilizes each HECC code to detect and correct any erroneous data bits in the corresponding data word and the data word over the system bus 620 to the processor 618. If the memory controller 606 detects any uncorrectable errors in data words, the controller typically reports such errors to an operating system (not shown) running on the processor 618. The operating system takes appropriate actions in response to such errors, such as notifying a user via one of the output devices 624 and terminating the execution of all programs on the processor 618.

To write data into the memory subsystem 604, the processor 618 applies an appropriate command along with the data words to be stored to the memory controller 606 over the system bus 620. In response to the command, the memory controller 606 generates the HECC code for the data word and applies a corresponding command along with the data word and HECC code to the DIMMs 610 over the memory bus 616. In response to this command from the memory controller 606, the DIMMs 610 access the appropriate memory locations and stores the data word along with the HECC code in these memory locations.

During operation of the computer system 600, the ECC logic 614 contained in each of the DIMMs 610 operates as previously described with reference to FIG. 4 or 5. In the following description, it is assumed the ECC logic 614 operates to perform vertical scrubbing as described with reference to the embodiment of FIG. 4. Accordingly, the ECC logic 614 in each DIMM 610 performs vertical scrubbing to detect and correct single bit errors and detect double bit errors. Upon detection of a double bit error, the ECC logic 614 notifies the memory controller 606 via the memory bus 616. In response to this notification, the ECC logic 622 in the memory controller 606 performs horizontal scrubbing on the appropriate DIMM 610 to detect and correct the error. Also note that the ECC logic 622 may also periodically perform background horizontal scrubbing to detect and correct errors in data words stored in the DIMMs using the HECC codes stored in the DIMMs as is done in conventional system memories.

In the embodiment of FIG. 6, the ECC logic 614 located in each of the DIMMs 610 allows the memory subsystem 604 to be utilized in existing computer systems that already provide conventional ECC corresponding to the HECC codes discussed herein. Moreover, by performing vertical scrubbing via the ECC logic 614 contained on the DIMMs 610 this additional level of error checking and correction does adversely affect by too much the throughput of the system memory 602. Where such throughput is not of too great a concern, the memory controller 606 also executes the vertical scrubbing functionality in another embodiment of the present invention.

In one embodiment of the computer system 600, the ECC logic 614 in each DIMM 610 performs vertical scrubbing during a refresh cycle of the associated DRAM memory devices 612. As will be appreciated by those skilled in the art, during a refresh cycle each memory location in the array of memory locations collectively formed by all devices 612 on each DIMM 610 is accessed to restore the data stored in each memory location. Since each memory location is being accessed, this is an opportune time for the ECC logic 614 to perform vertical scrubbing of these data bits. Thus, in one embodiment the ECC logic 614 on each DIMM 610 automatically performs vertical scrubbing during each refresh cycle of the associated DRAM memory devices 612. The ECC logic 614 could also automatically perform vertical scrubbing in response to some other parameter, such as some time period other than a refresh cycle such as once every X refresh cycle or Y times between each refresh cycle, or in response to a command from the memory controller 606.

Also note that the embodiments of the present invention are not limited to the type of memory contained in the system memory 602, and thus while the DIMMs 610 include the DRAM memory devices 612 in FIG. 6 in other embodiment the system memory includes one or more additional types of memory, such as static random access memory (SRAM), FLASH memory, and any other type prone to data bit errors as well.

Even though various embodiments and advantages of the present invention have been set forth in the foregoing description, the above disclosure is illustrative only, and changes may be made in detail and yet remain within the broad principles of the present invention. Moreover, the functions performed by the components 602-628 in the computer system 600 of FIG. 6 can be combined to be performed by fewer elements, separated and performed by more elements, or combined into different functional blocks depending upon the particular design and application of the computer system, as will appreciated by those skilled in the art. Therefore, the present invention is to be limited only by the appended claims.

What is claimed is:

1. A method of detecting and correcting errors in an array of memory locations arranged in rows and columns, each memory location storing a bit of data and the method comprising:
generating a horizontal error correcting code for each row of memory locations, the error correcting code capable of being used in detecting errors of multiple bits in the associated row and capable of being used in correcting errors of at least one bit in the associated row;
storing each horizontal error correcting code in some of the memory locations;
generating a vertical error correcting code for each column of memory locations, the error correcting code capable of being used in detecting errors of at least one bit in the associated column;
storing each vertical error correcting code in some of the memory locations;
detecting and correcting errors in each row of memory locations using the horizontal error correcting code generated for that row; and
detecting and correcting errors in each column of memory locations using the vertical error correcting code generated for that column.

2. The method of claim 1 wherein each horizontal error correcting code comprises a single error correction double error detection (SECDED) code.

3. The method of claim 1 wherein each vertical error correcting code comprises a single error correction double error detection (SECDED) code.

4. The method of claim 1 wherein each vertical error correcting code comprises a single parity bit.

5. The method of claim 1 further comprising:
periodically generating the vertical error correcting codes; and
when any of the vertical error correcting codes indicates an error in one or one bits in the associated column of memory locations,
correcting errors in the associated column of memory locations using the corresponding vertical error correcting code;
when any of the vertical error correcting codes indicates an error of more bits in the associated column of memory locations than can be corrected by the corresponding vertical error correcting code,
correcting errors in any of the rows of memory locations using the horizontal error correcting codes.

6. The method of claim 5 wherein the memory system includes refresh cycles and wherein periodically generating the vertical error correcting codes occurs during refresh cycles of the memory system.

7. The method of claim 5 wherein each vertical error correcting code is a parity bit.

8. A memory module, comprising:
a plurality of memory devices, each memory device including a plurality of memory devices that are collectively operable to store data in a plurality of memory locations arranged in rows and columns; and
error logic coupled to the memory devices, the logic operable to generate a vertical error correcting code for each column of memory locations on the memory module and to store each vertical error correcting code in the memory devices, and operable to detect and possibly also correct errors in any of the columns of memory locations using the corresponding vertical error correcting codes.

9. The memory module of claim 8 wherein each vertical error correcting code comprises either a SECDED code.

10. The memory module of claim 8 wherein each vertical error correcting code comprises a parity bit.

11. The memory module of claim 8 wherein the error logic comprises internal circuitry formed in each of the memory devices, with the internal circuitry for each device operable on memory locations contained within that memory device.

12. The memory module of claim 8 wherein each memory device comprises a DRAM.

13. The memory module of claim 8 wherein the memory module comprises a DIMM.

14. A memory system, comprising:
at least one memory module, each module including a plurality of memory devices that are collectively operable to store data in a plurality of memory locations arranged in rows and columns;
error correction circuitry coupled to each of the memory modules, the error correction circuitry operable for each memory module to generate a vertical error correcting code for each column of memory locations on the memory module and to store each vertical error correcting code in the memory devices on the memory module, and operable to detect and possibly also correct errors in any of the columns of memory locations using the corresponding vertical error correcting codes; and
a memory controller coupled to each of the memory modules, the memory controller operable to generate a horizontal error correcting code for each row of memory locations on each of the memory modules and to store each horizontal error correcting code in the memory devices on that memory module, and operable to detect and correct errors in any of the rows of memory locations on each module using the corresponding horizontal error correcting codes.

15. The memory system of claim 14 wherein the error correction circuitry is part of the memory controller.

16. The memory system of claim 15 wherein the error correction circuitry includes portions that are located on each memory module, each portion of the error correction circuitry being operable to generate the vertical error correcting codes for the associated memory module on which the circuitry is located.

17. The memory system of claim 16,
wherein the portion of the error correction circuitry on each module is operable to automatically generate the corresponding error correcting vertical codes; and
wherein the memory controller is further operable, when the portion of the error correction circuitry for a given memory module detects an error in any of the columns of memory locations that cannot be corrected using the corresponding vertical error correcting code, to detect and correct errors in the rows of memory locations on the given memory module using the corresponding horizontal error correcting codes.

18. The memory system of claim 17 wherein each of the memory devices on each memory module comprises a DRAM, and wherein the portion of the error correction circuitry on each module automatically generates the corresponding error correcting vertical codes during a refresh cycle of the DRAMs on that module.

19. The memory system of claim 14 further comprising:
a chipset including the memory controller;
a processor coupled to the chipset through a front side bus;
at least one input, output, and mass storage device coupled to the chipset.

20. The memory system of claim 19 wherein the memory system in combination with the chipset, processor, and other devices forms functions as a server computer system.

21. The memory system of claim 19,
wherein the memory controller is further operable to generate a signal indicating the detection of an error that cannot be corrected, and
wherein bits in pages of data accessed by the memory controller are distributed among the memory modules in such a way as to allow the memory controller to correct erroneous bits in an accessed page of data even upon the failure of one of the memory modules.

22. The memory system of claim 14,
wherein the error correction circuitry stores each vertical error correcting code in the same column of memory locations containing the data that was utilized in generating the vertical error correcting code; and
wherein the memory controller stores each horizontal error correcting code in the same row of memory locations containing the data that was utilized in generating that horizontal error correcting code.

23. A method of detecting and correcting errors in data bits of data words stored in a system memory, each data word including a plurality of data bits and the method comprising:
generating a horizontal error correcting code for each data word;
storing each horizontal error correcting code in the system memory;
generating vertical error correcting codes, each vertical error correcting code being generated using a particular bit from all of the data words;
storing each vertical error correcting code in the system memory;
performing vertical scrubbing using the vertical error correcting codes to detect errors in the data words; and
performing horizontal scrubbing using the horizontal error correcting codes to detect and correct errors in the data words.

24. The method of claim 23 wherein performing vertical scrubbing further includes detecting any corrected errors and wherein performing horizontal scrubbing is done only when the operation of performing vertical scrubbing detects errors that cannot be correct through the vertical scrubbing.

25. The method of claim 24 wherein each of the horizontal and vertical error correcting codes is a Hamming SECDED code.

26. The method of claim 23 wherein each of the horizontal error correcting codes is a Hamming SECDED code and each of the vertical error correcting codes is a single parity bit.

27. The method of claim 26 wherein performing horizontal scrubbing is done only when the operation of performing vertical scrubbing detects at least one error.
